(19) United States
(12) Patent Application Publication
(10) Pub. No.: US 2021/0110169 A1
(43) Pub. Date: Apr. 15, 2021

(54) Outdoor Device with Electronic Component

(71) Applicant: CGF Counsel Group Frankfurt AG, Frankfurt (DE)

(72) Inventors: Harald Rupp, Langenbach (DE); Wilhelm Treiber, Untersiemau-Ziegelsdorf (DE)

(73) Assignee: CGF Counsel Group Frankfurt AG, Frankfurt (DE)

(21) Appl. No.: 17/066,052

(22) Filed: Oct. 8, 2020

(30) Foreign Application Priority Data
Oct. 10, 2019 (DE) 10 2019 007 057.7

(51) Int. Cl. G06K 9/00

(52) U.S. Cl. CPC G06K 9/00785; G06K 9/00771

(57) ABSTRACT

A device, such as an outdoor device, with an electronic component arranged operably in a cavity of the device. The electronic component is electrically connected to an electrical functional unit of the device, wherein the electronic component includes a component housing. The component is a heat sink for the electronic component, and the electronic component is mechanically fixed by the component housing in a cavity of the device.

### TECHNICAL FIELD

This disclosure relates to an outdoor device with an electronic component operably arranged in a cavity of the outdoor device. The outdoor device preferably comprises an electrical functional unit of the outdoor device that is to be operated. The electronic component is, for example, an energy supply component or a network component, such as an active coupling element in a network, like a network switch or network router, for this electrical functional unit. The electronic component is operably arranged by means of its component housing in the outdoor device and is mechanically fixed there.

### BACKGROUND

A pole, as an example of an outdoor device, is a ubiquitous part of the urban and rural landscape. For example, a pole including an electrical light functional unit, i.e., a lighting device, may be arranged along a street or a sidewalk in order to help a motorist and/or pedestrian to better see or to have better orientation at night. Additionally or alternatively, an electronic information functional unit, such as traffic signs, traffic lights, traffic counters or toll controllers, that is used to monitor and control a traffic flow on the street or sidewalk may be arranged on a pole. Additionally or alternatively, an observation or monitoring device, such as a camera or a traffic counter, may be arranged on a pole as an electrical functional unit serving to observe and monitor squares or streets.

Such a pole is preferably an outdoor device of a so-called smart city concept. Smart city is a collective term for a holistic development concept that aims to render a landscape, in particular cities, efficient, technologically advanced, ecological, and socially inclusive. These concepts should be energy-efficient, low-emission, safe and cost-effective in order to enable future projects such as area-wide broadband networking, extensive e-mobility, traffic observation and/or monitoring and/or increased security. For this purpose, the outdoor devices are equipped with electrical functional units or the existing electrical functional units of the outdoor devices are used in the smart city concept.

The smart city concepts may require a network, if necessary, in order to exchange data between the electrical functional unit and a remote network component. This network is a critical network that may be exposed to cyber-attacks.

The smart city concepts may require an energy supply for supplying the electrical functional unit with energy.

The problem with the known solutions is that the outdoor device only has very limited space for an energy supply or the provision of network access. Common and typical housing or carrier concepts can therefore not be implemented. A new housing or carrier solution is required to provide network access and/or energy supply.

On the one hand, this new housing or carrier solution must be robust in order to enable unaffected functionality or operational readiness for network access and energy supply despite environmental influences in the outdoor area such as precipitation, temperature fluctuations, and storms.

In addition, an increasing number of electrical functional units on an outdoor device or new electrical functional units (such as charging stations for electric vehicles) cause greater energy requirement or power consumption per outdoor device. This greater energy requirement or increased power consumption results in greater heat development in components that provide network access and/or energy supply. Due to the limited space available in the outdoor device, the greater heat development results in faster overheating of the component providing the network access or energy supply. This increases the risk of a functional failure of the electrical functional unit. In addition, complex cooling measures such as water cooling, heat pipes, fans, and blowers are used for heat dissipation. These complex cooling measures are expensive, difficult to maintain and not fail-proof enough in an outdoor area.

Another problem with the known solutions is that the data exchange between a remote network component, for example a server, a base network component (backbone component), and an electrical functional unit is no longer secured against cyber attacks. An attacker who wants to manipulate the electronic functional unit, for example, is not yet being recognized by a remote network component and may thus cause considerable damage in the network and subsequently in the “smart city” concept. For example, an attacker may manipulate a light or traffic light control, sabotage a charging process for an electric vehicle and/or tap unauthorized data from the electrical functional units for own purposes. Also, the security-relevant data used in data communication, such as private keys, certificates, IP addresses or passwords, could be read out in an unauthorized manner.

All previous solutions are directed at improving the design of the outdoor device itself and making it more secure, in particular through complex cooling measures and mechanical or electronic barriers. Such adaptations to existing and already installed outdoor devices (i.e., to an existing infrastructure) are expensive and undesirable. In addition, these measures are inefficient when the outdoor device is installed in remote (less frequented) outdoor areas.

### SUMMARY

Several objects include providing a new housing or carrier solution, as mentioned above, for an electronic component for providing network access and/or energy supply for an outdoor device. Such a housing concept for an electronic component should, in particular, be implementable in a cavity of an outdoor device with limited space. In particular, such a new housing concept for an electronic component for an outdoor device is intended to implement effective heat dissipation in a simple manner. Also, attempts at attack or manipulation should be reliably detected and prevented.

Another object is compliance with data privacy, as publicly recorded data of an electrical functional unit may be subject to confidentiality and must be protected from unauthorized access.

In addition, further use of existing infrastructure should be made, if possible, in an almost unchanged manner. The replacement of an already installed outdoor device (such as a pole) in order to provide additional functionality should be avoided. There should also be no structural changes to the existing outdoor device (e.g., a pole), such as enlarging an opening or a cavity or attaching sensors or locking elements to the outdoor device.

In addition, wiring work in an existing outdoor device should be kept minimal.

With the foregoing and other objects in view, various embodiments include an outdoor device with an electronic component operably arranged in a cavity of the outdoor device. The electronic component is electrically connected to an electrical functional unit of the outdoor device. The electronic component has a component housing. The component housing is also a heat sink for the electronic component. The electronic component is mechanically fixed in a cavity of the outdoor device by way of the component housing. The electronic component or the component housing is fixed in a manner completely spaced apart from the inner sides of the outdoor device. The outdoor device has an opening for inserting the electronic component into the cavity.

In accordance with certain features, the outdoor device is a device stationarily installed in an outdoor area such as a public or private square of a city or a rural area. As such, in the outdoor area, this outdoor device is exposed to environmental influences such as weather, vandalism, and accident scenarios.

For example, an outdoor device may be street furniture (also called city furniture). Street furniture is a generic term for objects in an outdoor area, a public and private space, on a square or in a park. Street furniture provides a function required in public space or is used for information or advertising. For example, street furniture comprises lighting bodies, traffic lights or traffic signs.

For example, an outdoor device may be a hydrant, a telephone distribution box, a power supply box, an advertising column, or a taxi column.

Further, an outdoor device may be a pillar-like hollow body, such as a pole. A pole is a structure with at least a hollow pillar-like or post-like interior area. The base area is comparatively small compared to the height thereof. The pole is primarily used to attach functional units, such as lighting equipment (light pole for street lighting, floodlight, path light, luminous advertising) and/or units for monitoring and/or directing traffic (signposts, traffic lights, traffic signals, traffic signs, toll bridges, traffic counters) and/or electrical components such as antennas.

In accordance with certain features, the outdoor device has a cavity. The cavity may extend over the entire internal volume of the outdoor device. Then, the outdoor device is a hollow body, for example in the form of a hollow cylinder or a hollow cone or a hollow truncated cone. Alternatively, only a portion of the outdoor device is provided with a cavity, as a result of which the remaining part of the outdoor device remains as a solid and stable part, as is the case, for example, with a solid pillar.

Further, the cavity may be, for example, round, oval, triangular, square or polygonal in cross section.

In accordance with certain other features, the electronic component may be, for example, an active network component of a network, that is, a physical device required for data exchange (communication and interaction) between a network component remote from the outdoor device and an electrical functional unit. The electronic component may, for example, be or comprise a gateway, a router, a network bridge, a modem, a wireless access point, a network switch, a network distributor (hub) and/or a repeater. The electronic component may also be or comprise a hybrid network component such as a multilayer network switch, a protocol converter, a bridge router, a proxy server, a firewall, a network address translator, a multiplexer, and a network interface controller.

In accordance with certain features, such an electronic component is a network switch. For example, the network is a Metropolitan Area Network, MAN for short. The network may be set up in a specific bus topology, for example as a star bus or a serial bus (so-called daisy-chaining). In a daisy chain topology, a number of hardware components are connected in series to form a network. The first electronic component in a first outdoor device is directly connected to the remote network component. The other electronic components are incorporated in the other poles and each connected to their predecessors (series connection principle). This creates a chain, the so-called daisy chain. Now, the signal to and from an electronic component in an outdoor device, here primarily a pole, is transmitted via predecessors thereof to the remote network component.

Alternatively or additionally, the electronic component may be, for example, an energy supply component for an electrical functional unit of the outdoor device. For this purpose, the electronic component may comprise an energy supply unit, wherein the energy supply unit has a first energy port for supplying a supply energy external to the component and at least one second energy port for diverting supply energy for the functional unit of the outdoor device.

In accordance with certain features, the electronic component may be an active electrical component, which differs from passive electrical components in the presence of electronics in the interior of the component housing.

In accordance with certain features, the electronic component includes a component housing. The component housing is the carrier of the electronic component. The component housing includes in the housing interior the electronic component with, for example, a sensor, a control unit and/or an energy supply unit. The component housing serves to protect the electronic component against touch, intrusion of foreign objects and water as well as for shock resistance. For example, the component housing has protection class IP67. Further, the component housing enables the electronic components to operate in an ambient temperature range of −20 to +85° C. and an ambient humidity of 5% to 95%.

In accordance with certain other features, the component housing may also function as a heat sink for the electronic component. The component housing may have, for example, a thermal resistance of more than 1.0 K/W. The heat sink enlarges a heat-emitting surface of an electronic component located inside the housing. This can prevent possible damage to the electronic components from overheating. To increase the surface area of the component housing, cooling ribs and cooling fins may be provided, for example, on one or more outer sides of the component housing.

In accordance with certain other features, the design of the component housing as a heat sink ensures sufficient heat dissipation and further cooling measures, such as fans, water cooling, heat pipes, etc. for dissipating the heat generated by the electronic component can be omitted. The overall structure is therefore less complex, reduced in size and therefore more cost-effective.

In accordance with certain features, the component housing may be made of a metal. For example, aluminum may be used as the housing material due to its very good ratio of weight to thermal conductivity. Generally, a lower weight ensures a reliable mechanical fixation in the cavity of the outdoor device with minimal effort.

In accordance with certain other features, the component housing has a maximum dimension that allows for simple mounting (for installation) and also simple removal (for uninstallation, maintenance, repair) of the electronic component in the cavity of the outdoor device, in particular a hollow pole or a hollow pillar.

Further, the component housing has minimum dimensions that allow the component housing to be used as a heat sink for the electronic component, with internal heat sinks or additional fans/blowers or other complex heat dissipation measures (heat pipes, water cooling) being omitted.

As mentioned above, the electronic component may be arranged, for example, within a stationarily installed outdoor device. The electronic component may be mechanically fixed by way of the component housing in a cavity of the outdoor device. Fixing the electronic component in the outdoor device allows for the electronic component to be held permanently in a defined position and orientation. In this way, stability is provided, guaranteeing the functionality of the electronic component.

In accordance with certain features, the position and orientation of the component housing is selected such that maximum heat dissipation away from the housing is facilitated. Herein, the structural features of the outdoor devices should be taken into account. Preferably, a longitudinal extension of the component housing in the fixed state corresponds to a longitudinal extension of the outdoor device. In addition, a sufficient distance from other heat sources in the cavity of the outdoor device should be maintained.

Accordingly, the electronic component may be fixed completely spaced apart from the inner side(s) of the outdoor device. The inner surfaces of the cavity, that is the interior of the outdoor device, are referred to as inner sides. In this context, primarily inner side surfaces oriented in parallel to a longitudinal axis of the outdoor device are meant.

Further, the component housing may be arranged centrally in the cavity. Each side surface of the component housing thus has a sufficient distance from the inner side surfaces of the outdoor device. The component housing is preferably oriented towards a center point of the cavity. This ensures that the component housing is enclosed by air as evenly as possible, so that colder air can flow around all sides of the electronic component. If the electronic component is inserted into a pole, this arrangement ensures optimal heat dissipation due to the chimney effect inside the pole without the need for additional cooling measures such as fans or blowers.

In accordance with certain features, the electronic component may be installed and removed as an additional component in the outdoor device, for example. The outdoor device may thus be retrofitted with such an electronic component in order to provide higher functionality.

In accordance with certain features, the cavity of the outdoor device is accessible from outside the outdoor device. For this purpose, the cavity has an opening for inserting the electronic component into the cavity. The opening also serves to remove the electronic component from the cavity, for example in order to be able to perform a maintenance measure on the outdoor device or to make a replacement of the electronic component or the electrical functional unit. This opening is limited in its dimensions due to structural and static requirements of the outdoor device so that retrofitting an outdoor device requires that the electronic component can be placed and fixed in the cavity through this opening. The external dimensions of the component housing are, therefore, predetermined by the dimensions of the opening, and maximization of the surface area of the component housing to improve heat dissipation is thus limited by the dimensions of the opening. According to some embodiments, a length dimension of the opening is greater than a width dimension of the component housing of the electronic component.

The opening may be closed mechanically by a door or cover. As such, the electronic component is safely accommodated in the outdoor device and is additionally protected against environmental influences such as moisture, temperature, vandalism, and external forces such as collisions (accidents) or storms. In addition, further use of the existing infrastructure of the outdoor device is made and a replacement of, for example, poles to provide additional functionality can be avoided.

The opening may have standard dimensions in the outdoor device.

As mentioned above, the electronic component is arranged operably in the outdoor device. In this context, operably means that the electronic component is supplied with energy and installed in a mechanically fixed manner. The energy supply for the electronic component may be provided within the outdoor device in addition to the energy supply of an electrical functional unit of the outdoor device. For example, the energy supply for the electronic component could be diverted from the energy supply of an electrical functional unit of the outdoor device.

In accordance with certain features, the electronic component is electrically connected to the electrical functional unit. This connection is used either to supply energy from the electronic component to the electrical functional unit or to transmit a data signal between the electronic component and the electrical functional unit, that is both to send and/or receive the data signal in the electronic component.

According to exemplary embodiments, the outdoor device includes a fastening element, wherein the fastening element may be arranged in parallel to a longitudinal axis of the outdoor device in the outdoor device in order to mechanically fix the component housing in the cavity of the outdoor device in parallel to a longitudinal axis.

In accordance with certain features, the fastening element may be mechanically fixed on an inner longitudinal side of the outdoor device in order to mechanically fix the component housing in the cavity of the outdoor device.

Here, the fastening element is a structural component in the cavity of the outdoor device and is either an integral part of the outdoor device or an additional component of the outdoor device. The fastening element is sufficiently stable to carry the component housing in the cavity and to fix it mechanically. Accordingly, the fastening element may be mechanically detachably and non-detachably connected to the outdoor device at a plurality of points. The fastening element is, for example, a rail guide arranged in the cavity of the outdoor device, such as a metal rail that, for example, is a top-hat rail or perforated rail. The fastening element is, for example, welded, screwed, or riveted to the outdoor device. The component housing is directly or indirectly (via holding elements or holding devices) mechanically fixed to the fastening element.

According to exemplary embodiments, the component housing includes at least one holding region on an outer side of the component housing. A holding device engages the holding region in a form-fitting manner. The holding region is, for example, a recess, a depression, a hole or a cavity. In a simple form, the holding region may be a hole or a slot into which the holding device engages in a form-fitting and/or force-fitting manner. For this purpose, the holding device may have corresponding protrusions, pins or areas which engage as accurately fitting as possible with the holding regions in order to hold the component housing. According to certain embodiments, two holding regions are provided on opposite outer sides, such as an upper side and a lower side, and both are arranged perpendicular to a longitudinal axis of the electronic component.

In accordance with certain features, the holding device is mechanically or magnetically connected to the fastening element of the outdoor device. This achieves the mechanical fixation of the electronic component. The configuration with the holding device and holding regions ensures the spacing from the inner side of the outdoor device and thus enables an air flow around the entire component housing for optimal dissipation of heat generated by the electronic component.

According to an exemplary embodiment, the holding element is connected to the fastening element of the outdoor device in a mechanically releasable manner by a clamp connection, a latching connection, a clip connection and/or a screw connection. These simple connection concepts allow for the electronic component to be easily installed and uninstalled in the cavity of the outdoor device which is limited in space.

According to an exemplary embodiment, the component housing may function as a heat sink for a control unit and/or an energy supply unit within the component housing of the electronic component. Wherein these units are the cause for the majority of the heat generated by the electronic components, their cooling by the component housing configured as a heat sink reduces the risk of overheating or heat build-up and, as a result, the failure/defect of the electronic component.

In accordance with certain features, the component housing has at least one protrusion on an inner side of the component housing. The protrusion may be parallel to a base plane of the inner side from which the protrusion protrudes. The protrusion protrudes into the interior of the component housing. This makes it possible to reduce a distance between heat-generating units of the electronic component and thus enables an improved thermal coupling for dissipating generated heat. The control unit and/or the energy supply unit are may be disposed directly opposite the electronic component. Furthermore, the control unit and/or the energy supply unit may be disposed in such a manner as to make direct contact with the electronic component. The direct contact may also include placing a heat sink pad or a thermal paste between the protrusion and the corresponding unit of the electronic component. Further, an area of an upper side of the protrusion furthest away from the base plane of the inner side may be equal to or greater than the surface of the heat-generating unit in the electronic component. This configuration makes it possible to omit further heat sinks in the interior of the component housing, as a result of which the dimensions of the component housing can be reduced without reducing its cooling capacity. The protrusion may be an integral part of the component housing or of at least an outer part of the component housing. As a result, the component housing can be manufactured in a simplified manner and very good heat coupling is achieved.

In accordance with certain features, the electronic component may have electrical and/or optical ports exclusively on a top side and/or a bottom side of the electronic component opposite the top side, the top side and the bottom side of the component housing of the electronic component. This top side and/or bottom side are oriented substantially perpendicular to a longitudinal axis of the outdoor device. With such an arrangement, the small space in the cavity of the outdoor device is optimally used for heat dissipation because the dimensions of the component housing can be maximized in transverse orientation, which would not be possible if ports were placed on a lateral surface of the component housing. In addition, the structure of the component housing can be simplified in this way. In particular, when a multi-part housing is provided, two lateral parts can be provided with cooling ribs over the entire surface. In addition, cable routing in the cavity of the outdoor device can be optimized without impairing an air flow for cooling.

According to an exemplary embodiment, the component housing is multi-part, wherein a first lateral part of the component housing is detachably connected to a second lateral part of the component housing in a form-fitting manner. The lateral parts can be better combined by appropriate forms, for example tongue and groove connections or tapers (lips) on the connecting surfaces, thereby increasing the stability of the component housing and also improving the electromagnetic compatibility. The desired protection class, for example IP67, of the housing can thus be established in a simplified manner. The lateral parts may have cooling fins on the outer sides in order to improve the heat dissipation. Further, the lateral parts may be extruded parts.

In accordance with certain features, the component housing includes at least one printed circuit board in a form factor, such as a PC/104 form factor.

Furthermore, the electronic component may comprise a control unit. According to exemplary embodiments, the control unit includes at least one first data port configured to transmit a data signal between the electronic component and a network component remote from the outdoor device, and at least one second data connection configured to transmit a data signal between the electronic component and the functional unit of the outdoor device, wherein the control unit is configured to forward data communication between the remote network component and the electrical functional unit of the outdoor device.

According to exemplary embodiments, the electronic component comprises a sensor on the component housing, the sensor being configured to: provide a sensor signal, wherein a control unit of the electronic component is configured to evaluate the received sensor signal, recognize a change in the sensor signal, and alert a network component remote from the outdoor device when the change in the sensor signal is recognized by the control unit.

According to further exemplary embodiments, the electronic component comprises a sensor, also referred to as a detector or (measured quantity or measuring) pick-up or (measuring) probe. The sensor is a technical component able to sense certain physical properties (e.g., amount of heat, temperature, humidity, pressure, sound field quantities, brightness, acceleration) qualitatively or quantitatively as a measured quantity. These quantities are sensed by means of physical effects and converted into an electrical sensor signal that can be processed by the control unit and provided thereto. In this case, the control unit may perform the conversion for provision or the sensor performs this conversion and provides the sensor signal.

In accordance with certain features, the sensor is attached to the component housing. For this purpose, the sensor may be arranged in the interior of the component housing and configured, by means of a passage or a transparent partial region of the component housing for the property to be detected, to detect the physical property existing outside the component housing even inside the component housing. Alternatively, the sensor may also be arranged inside the component housing if the detection of the physical property is not impaired by the presence of the component housing, for example for detecting a movement of the electronical component.

According to exemplary embodiments, the control unit of the electronic component has at least one first data port for transmitting a data signal. Additionally, the energy supply for the electronic component or the control unit may also be received via this data signal in order to establish operability within the outdoor device, such as a pole. The data signal would then be combined with a Power-on-Ethernet signal, for example.

Further, the at least one first data port may serve to transmit a data signal between the electronic component and a remote network component, such as a component of a base network (backbone) and/or a data center and/or a server and or another electronic component integrated into another pole (or outdoor device). The distance between the outdoor device and said remote network component may range from a few meters to several hundred kilometers.

In accordance with certain features, the at least one first data port may be connected to a first port of the electronic component, the control unit further has at least two first data ports, with each configured to transmit a data signal between the electronic component and at least the network component remote from the pole, and wherein each first data port may be connected to a first port of the electronic component. Thus, the electronic component may be connected to more than one remote network component or may provide a larger data bandwidth for the peripherals. The first port is, for example, a small form-factor pluggable, SFP, port for saving space. Alternatively, a daisy chain topology can be set up with two first ports.

In accordance with certain other features, the control unit of the electronic component has at least one second data port for transmitting a data signal. Using this data signal, the electronic component may also additionally provide the supply energy for the electrical functional unit of the outdoor device in order to establish operability, in particular the energy supply, of the electrical functional unit of the outdoor device. The data signal would then be combined with a Power-on-Ethernet signal, for example.

Further, the at least one second data port may be connected to a second port of the electronic component, the control unit further has at least four second data ports, with each configured to transmit a data signal between the electronic component and an electrical functional unit of the outdoor device, and each second data port may be connected to a second port of the electronic component. The number of second data ports is not restricted herein and could also be, for example, eight, twenty-four or more. A device thus enables great functionality on just one outdoor device. The second port is, for example, an RJ45 compliant port.

In accordance with certain features, a data signal via each second data port may be encrypted individually. The data signals of different second data ports are therefore not visible among each other, so that different service providers can be connected to different electrical functional units of the outdoor device via the same device without the service providers being able to eavesdrop on the data traffic among each other.

For purposes of this disclosure, any functional unit on the pole may be regarded as an electrical functional unit of the outdoor device (hereinafter also simply referred to as peripheral). The electrical functional unit of the outdoor device may be a sensor or an actuator. It may be an electrical functional unit of the outdoor device (pole) itself, that is, for example, a lighting means, a light sign system, a light signal system, a toll component and/or an antenna. In addition or alternatively, the electrical functional unit of the outdoor device may also be a device to be installed on the outdoor device, such as a traffic monitoring unit, an additional light signal control, a camera, a wireless network access point (WLAN-AP), a cellular base station, an electric vehicle charging station, and the like. For example, the electrical functional unit of the outdoor device may be a smart city component, such as a component of a smart real-world laboratory, with additional intelligent sensors that make it possible to sense a wide variety of information about the vicinity, in particular traffic, weather and the environment, and equip a stationary light pole to be a multimodal utility carrier with adaptive lighting, energy supply and broadband connection for various types of sensors.

According to exemplary embodiments, the peripheral includes, for example, sensors for measuring temperature, humidity, emissions, pollutants, road surface, etc. The peripheral may provide, for example, information on the traffic flow as the basis for a (central or local) optimization of the traffic flow. The peripheral may provide information, for example, in particular support in the search for free parking space or charging stations for electric vehicles or for an improved choice of means of transport, also in context of the current weather situation. The peripheral may increase security, for example by targeted surveillance using cameras. The peripheral could be part of “gamification”.

According to exemplary embodiments, the control unit of the electronic component is configured to forward data communication between the remote network component and the electrical functional unit of the outdoor device. This forwarding may be unidirectional or bidirectional. A standardized forwarding may be used, such as, for example, according to the IEEE 802.1x protocol, wherein a media access control (or MAC) address of an electrical functional unit of the outdoor device is used to secure the data communication.

According to further exemplary embodiments, the control unit of the electronic component may be configured to receive and evaluate the sensor signal from the sensor of the electronic component. The control unit may itself perform a conversion of a physical effect sensed by the sensor in order to obtain an electrical sensor signal for evaluation. Alternatively, the sensor is already equipped with a conversion unit and provides an electrical sensor signal that is only fetched by the control unit. The sensor may be supplied with energy via the control unit of the electronic component, via the device or via the sensor itself. The sensor may also be operated with energy supplied via an energy harvesting method.

According to further exemplary embodiments, the control unit of the electronic component is further configured to recognize a change in the sensor signal. For this purpose, for example, a value of the sensor signal, such as amplitude, frequency, phase and/or duration, is compared with a predefined reference value.

In accordance with certain features, the control unit of the electronic component is also configured to alert the remote network component when a change in the sensor signal has been recognized.

Thus, according to exemplary embodiments, the electronic component evaluates sensor signals from a sensor on the housing of the device and alerts the remote network component in the event of a corresponding abnormality in the sensor signal. Then, the network component may immediately interrupt the forwarded data connection as a countermeasure or move it to a quarantine zone in order to quickly counter a possible attack on the data connection and thus to prevent tapping of data or information of the remote network component or the electronic component. With this electronic component, such as a network node that is far away from a data center or a backbone but has full access to the provided data connection, is further secured by providing a sensor system that immediately alerts about a possible attack.

According to exemplary embodiments, the sensor generates a sensor signal as a function of light incident on the sensor, the change in the sensor signal being an abrupt or continuous increase in the sensor signal amplitude due to an increased incidence of light. Here, the sensor may be a light sensor, also referred to as a photo sensor or photo detector. With such a light sensor, the intensity of light with suitable wavelength can be measured. The sensor converts light into an electrical signal by means of a photoelectric effect or exhibits an electrical resistance that is dependent on the incident radiation. Since the device is arranged inside the pole, the inside of the pole is not accessible in normal operation, for example due to a locked pole door or pole cover, so that a defined, almost constant, low incidence of light is detected by the sensor in normal operation. When the pole is opened, for example by operating a pole door or pole cover, the incidence of light increases abruptly. The sensor detects this increase and alerts the remote network component.

According to further exemplary embodiments, the evaluation of the sensor signal includes averaging the values of the sensor signal over a predefined period of time (so-called mini-hysteresis). In this way, short-term fluctuations in the physical property to be recorded can be averaged out. For example, a flash of light (thunderstorm, etc.) in the vicinity of the pole will not necessarily trigger the (false) alarming of the remote network components due to abnormally high incidence of light. For example, a gust of wind (storm, etc.) on the pole will not necessarily trigger the (false) alarming of the remote network components due to abnormal movement of the housing.

According to further exemplary embodiments, the sensor is a motion sensor, wherein a change in the sensor signal is an abrupt or continuous increase in the sensor signal amplitude due to movement of the housing of the device. The motion sensor is, for example, an acceleration sensor, an inclination sensor or a global positioning system, GPS, transmitter. In normal operation, the electronic component in the outdoor device is fixed at the stationary pole and is therefore not exposed to any movement. The movement sensor detects any movement of the housing, for example if an attacker tries to manipulate ports of the device or if a thief tries to steal the device. The remote network component is then alarmed.

According to further exemplary embodiments, the sensor is a switching element, wherein a change in the sensor signal is an abrupt or continuous increase in the sensor signal amplitude due to the housing of the electronic component being opened. The switching element is arranged in or on the housing in such a way that opening the housing causes a switching state to be changed. The switching element is, for example, a micro switch or a reed contact or a magnetic contact.

According to exemplary embodiments, the control unit is configured to delete and/or overwrite at least security-relevant information stored in a memory of the device when the change in the sensor signal is recognized by the control unit of the electronic component. Alternatively, the entire memory content of the electronic component is deleted or overwritten. This further increases the security, since now, when an abnormality is recognized via the change in the sensor signal, the security-relevant information of the device is deleted. As a result, no data connection will be forwarded and every peripheral loses the data connection to the remote network component. The energy supply to the peripherals (electrical functional units) may also be disabled by the control unit of the electronic component, so that access to the data of the peripherals is no longer possible.

The confidential or security-relevant information relates, on the one hand, to configuration information of the electronic component, in particular IP addresses for the remote network component, private cryptographic keys of the electronic component, certificates of the electronic component, signature keys of the electronic component, a configuration file with connection parameter settings or, on the other hand, to access passwords, configuration passwords, blacklists of the electronic component or another electronic component, whitelists of the electronic component or another electronic component, access settings, and the like. User names and user passwords for authentication on the peripheral are also among the security-relevant information. The electronic component is therefore completely unconfigured and can neither establish a data connection to the remote network component nor forward a data connection to/from a peripheral. Manipulation via data tapping or peripheral remote control is therefore excluded.

According to further exemplary embodiments, the control unit is configured to delete and/or overwrite the security-relevant information only when the change in the sensor signal results in an abrupt or continuous increase in the sensor signal amplitude due to the housing of the electronic component being opened and/or due to the housing of the electronic component being moved. Moving the electronic component or opening the housing of the device is always evaluated as an attack and thus the deletion is forced. After opening the housing or moving the housing, the electronic component is completely unconfigured and can thus neither establish a data connection to the remote network component nor forward a data connection to/from a peripheral. Manipulation via data tapping or peripheral remote control is therefore excluded.

According to exemplary embodiments, at least two sensors are provided. A redundancy of sensor signals may thus be used in order to more reliably detect an attack on the device. In addition, two-stage alarming may also be provided. For example, when a sensor amplitude of the first sensor is detected to exceed a sensor signal threshold value, initially (only) the remote network component is alerted, and when a sensor amplitude of the second sensor is detected to exceed a sensor signal threshold value, further measures are taken in the electronic component itself, for example deleting or overwriting sensitive information.

According to exemplary embodiments, the electronic component further comprises an energy storage for providing supply energy to the control unit when an energy supply external to the device fails or is removed. The function of the sensor of the electronic component is thus further guaranteed and, in addition, energy for deleting or overwriting the memory of the electronic component is also ensured. Thus, even if the electronic component is disconnected in the event of theft or maintenance, operability even without energy supply is made possible.

Deleting or overwriting is also referred to as “zeroizing”.

According to further exemplary embodiments, the electronic component comprises an energy supply unit. The energy supply unit includes a first energy port (for example the first data port or an additional port) for supplying supply energy external to the component. The energy supply includes at least one second energy port for diverting supply energy to the peripheral, the second energy port providing a Power-on-Ethernet, PoE, energy signal which is combined with the data signal to be transmitted between the device and peripheral. In this way, it is possible to supply each peripheral and also each electrical functional unit of the outdoor device via one of the second data ports of the electronic component, thereby reducing the wiring work in the pole and eliminating the need to provide an additional energy supply for the peripherals. The energy supply may be an energy supply unit, the energy consumption of which is monitored and logged. In this way, abnormalities in the device itself or in the peripherals can be detected and reported to the remote network component.

According to further exemplary embodiments, the energy supply unit includes at least one third energy port for diverting supply energy for the control unit of the electronic component. The energy for the control unit is thus conditioned by electronic component itself and does not have to be provided externally.

According to further exemplary embodiments, the control unit of the electronic component is arranged on a printed circuit board with a standard form factor, such as PC/104, with the energy supply unit of the electronic component being arranged on a second printed circuit board with a standard form factor, such as PC/104. This industry standard allows for the electronic component to be miniaturized such that it can be arranged in the outdoor device without having to make structural changes thereto. In addition, this form factor is suitable for providing a large surface for components of the device such that good heat dissipation can be achieved. Choosing the same form factor also allows for multiple boards to be arranged one above the other, so-called “stacking”, and to be connected using plug-in connectors. This improves the electromagnetic compatibility of the components one the board with one another.

According to exemplary embodiments, the authentication of the peripheral for forwarding the data communication between the remote network component and the peripheral is performed based on the MAC address of the peripheral, wherein in the event of a failed authentication of the peripheral, the forwarding of the data communication is prevented by the control unit of the electronic component. In accordance with certain features, the data communication complies with the IEEE 802.1x protocol and enables secure communication. The MAC address of the peripheral may be advertised in the remote network component. This safeguard means that a peripheral installed on the electronic component is not exchangeable, wherein another peripheral at the second data port leads to a deactivation of the data connection to the peripheral.

### BRIEF DESCRIPTION OF THE DRAWINGS

Exemplary embodiments and advantages are explained in more detail below with reference to figures, the figures merely describing the exemplary embodiments. The same components in the figures are designated with the same reference symbols. With specially marked exceptions, the figures are not to be regarded as true to scale; individual elements of the figures may be shown exaggeratedly large or exaggeratedly simplified.

FIGS. 1A-1C show an outdoor device according to an exemplary embodiment, with a closable opening and an electronic component in the cavity of the outdoor device;

FIGS. 2A-2D show different views of a component housing of an electronic component according to an exemplary embodiment;

FIG. 3 shows a perspective view of a component housing of an electronic component, according to an exemplary embodiment thereof, in an exploded view without electrical components;

FIGS. 4A-4D show different views of a second lateral part of the component housing of an electronic component according to the exemplary embodiments in FIGS. 2 and 3;

FIG. 5 shows a perspective view of a first lateral part of the component housing of an electronic component according to the exemplary embodiments in FIGS. 2 and 3;

FIGS. 6A-6C show various views of a base of the component housing of an electronic component according to the exemplary embodiments in FIGS. 2 and 3;

FIGS. 7A-7D show various views of a cover of the component housing of an electronic component according to the exemplary embodiments in FIGS. 2 and 3;

FIG. 8 shows a perspective view of a component housing of an electronic component according to an exemplary embodiment thereof, in an exploded view with electrical components;

FIGS. 9A-9D show a variant for mechanically fixing a component housing of an electronic component in an outdoor device according to an exemplary embodiment;

FIG. 10 shows a simplified block diagram of an electronic component within a schematically illustrated pole portion according to an exemplary embodiment;

FIG. 11 shows a simplified block diagram of an electronic component according to an exemplary embodiment;

FIG. 12 shows a simplified block diagram of an electronic component according to an exemplary embodiment;

FIG. 13 shows a true-to-scale exemplary embodiment of an exemplary pole in which an electronic component, according to an exemplary embodiment thereof, is arranged;

FIG. 14 shows three true-to-scale exemplary embodiments of exemplary pole openings through which an electronic component, according to an exemplary embodiment thereof, is placed into a pole; and

FIG. 15 shows a system according comprising a pole with an electronic component arranged therein according to an exemplary embodiment.

### DETAILED DESCRIPTION

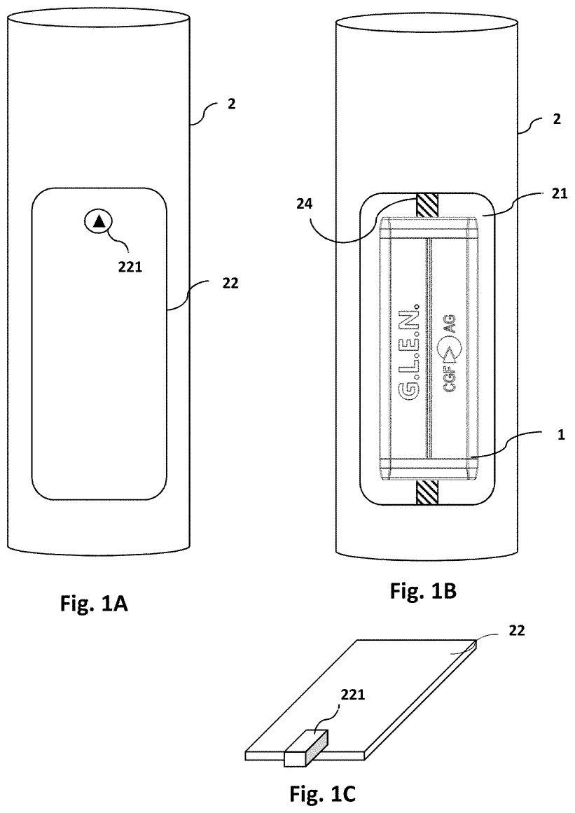

FIGS. 1A-1C show an exemplary embodiment of an outdoor device 2 with a closable opening 21 and an electronic component 1 in the cavity of the outdoor device 2.

FIG. 1A shows the outdoor device 2 as a partial portion of a pole 2. The pole 2 has an opening which is closed by means of a cover or door 22 by a locking element 221 of the cover 22. The locking element 221 operates a mechanical lever (see FIG. 1C) and is operated using a triangular key.

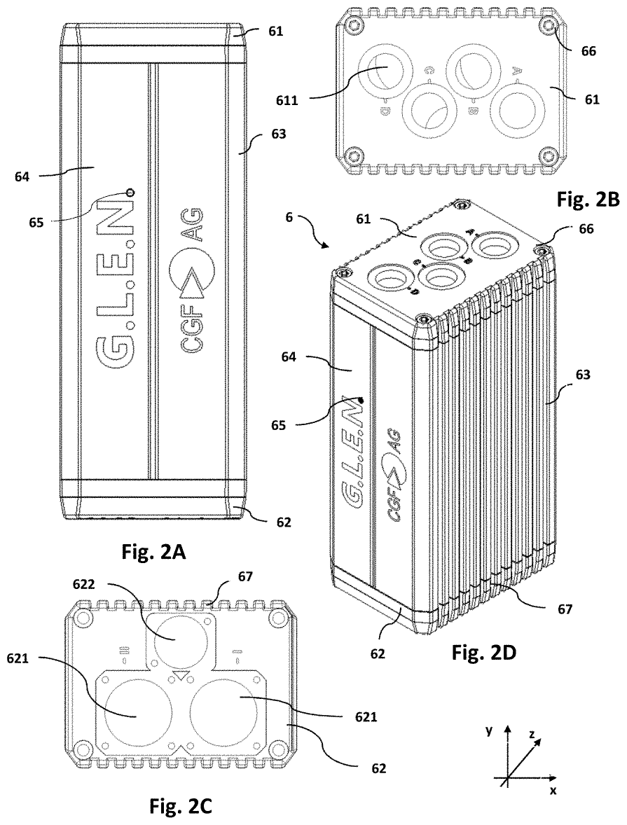

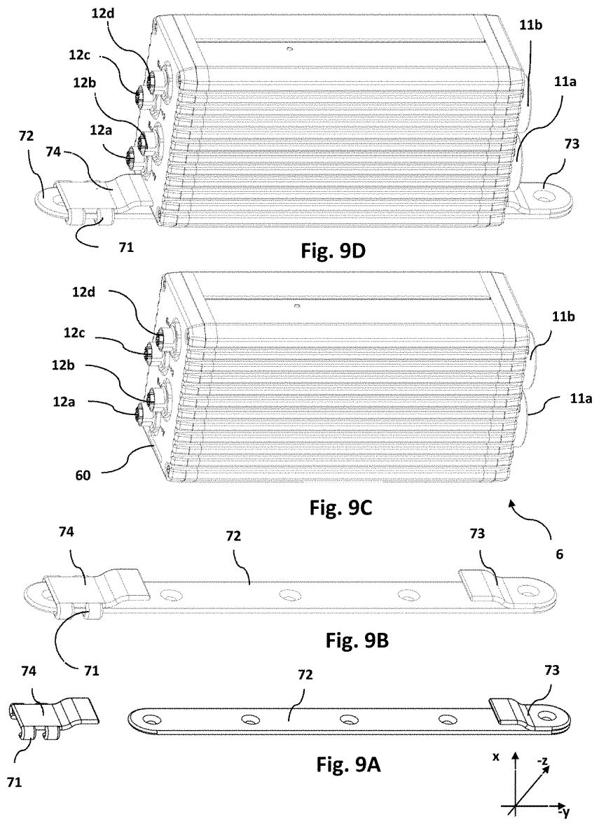

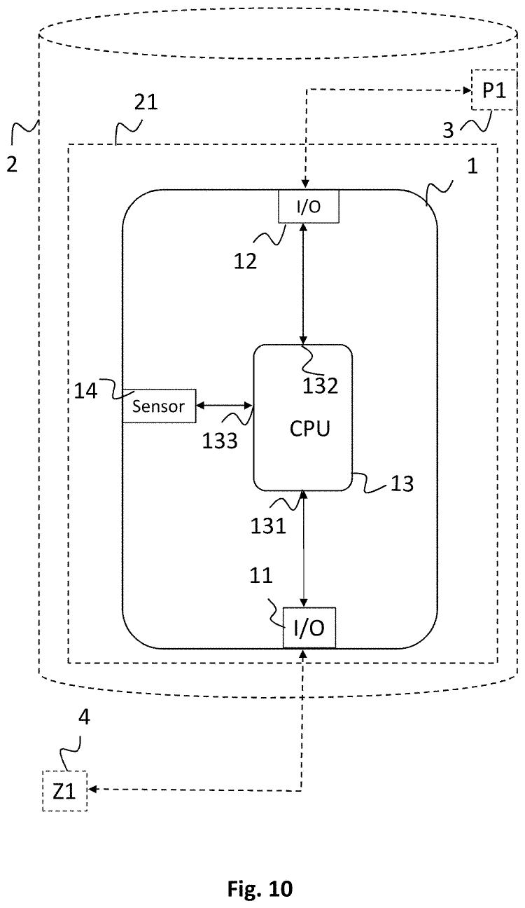

FIG. 1B shows the pole 2 shown in FIG. 1A with the door 22 removed. The pole 2 is hollow and houses an electronic component 1 discussed in detail in FIGS. 10 to 12. The electronic component 1 is arranged in mechanically fixed manner on a fastening element 24 in the cavity of the pole 2. FIG. 1B does not show any electrical connections; these are discussed in detail with respect to FIGS. 10 to 12. In FIG. 1B, it can be seen that the electronic component 1 has a component housing. This component housing is shown and described in detail in FIGS. 2-8. The component housing may function as a heat sink for the electronic component 1. The component housing is (as indicated in FIG. 1B) fixed completely spaced apart from the round inner side of the pole 2. A fastening variant is presented in FIG. 9.

This arrangement according to FIG. 1B enables an air flow around the electronic component 1 on each of its upper sides and thus enables efficient heat dissipation of the heat generated by the electronic components 1. This arrangement allows for the electronic component 1 in the pole 2 to be operated without additional cooling measures, such as a heat pipe, a fan or even water cooling. A chimney effect of the pole 2 provides sufficient flow around the electronic component 1 for heat dissipation. Due to the central arrangement in the pole 2, there is an equal flow around all upper sides of the electronic component 1.

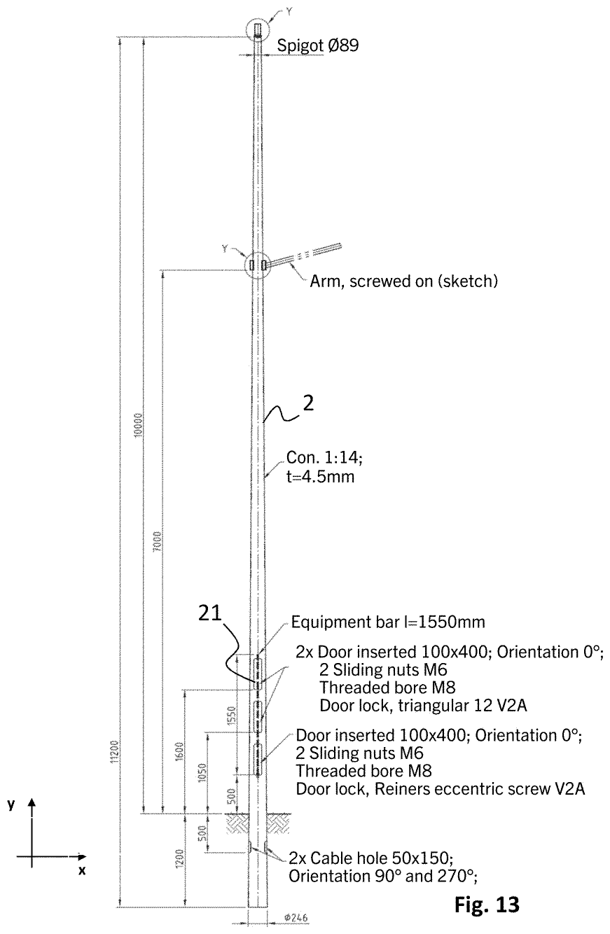

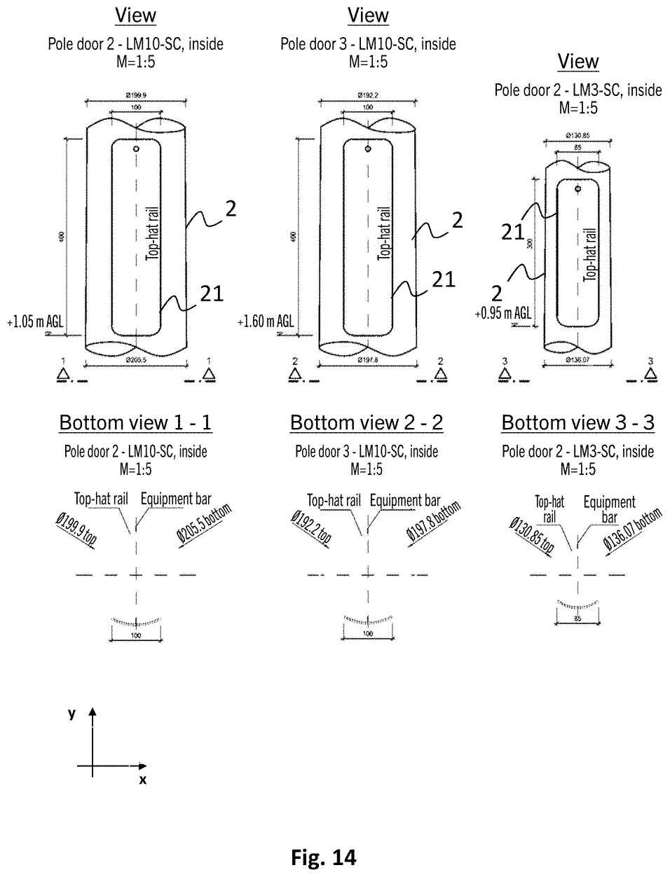

The electronic component 1 can be inserted (installed) into the cavity via the opening 21 and also removed again (uninstalled). Accordingly, the dimensions of the opening determine the dimensions of the component housing, as depicted in the true-to-scale drawings of FIGS. 13 and 14.

In FIG. 1C, the door 22 of the pole 2 is shown. This door 22 closes the opening 21 when the electronic component 1 is in operation. The closing is enabled via the locking lever 221 and a triangular key. According to this example, the pole 2 is thus a conventional pole that is retrofitted with the electronic component 1.

The pole 2 with the door 22 shown in FIGS. 1A to C is shown in detail in FIGS. 13 to 15 and reference is made to the associated description.

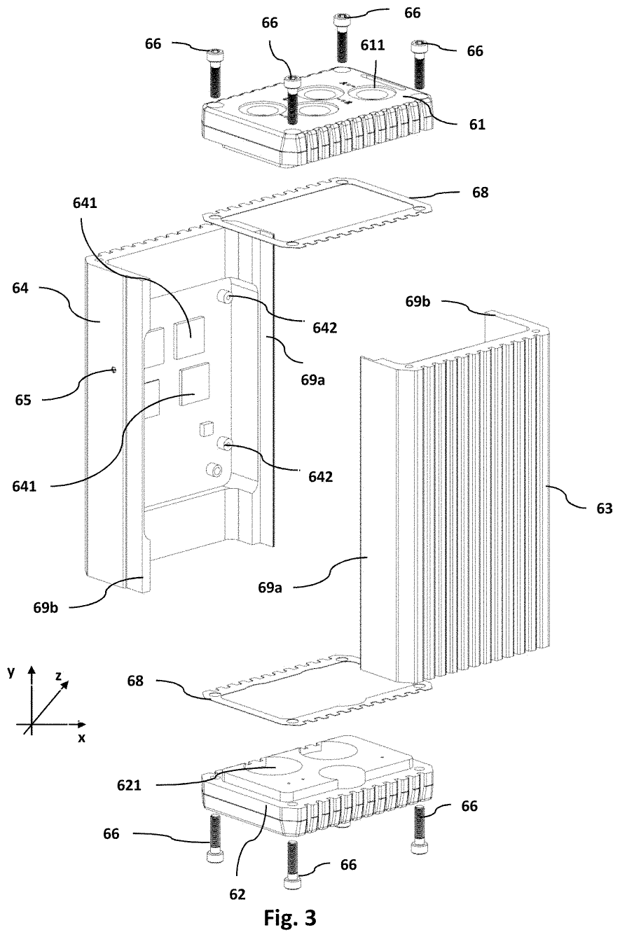

FIGS. 2A-2D show four different views of an exemplary embodiment of a component housing 6 of an electronic component 1, such as the electrical component described with respect to FIGS. 1 and 10 to 12. FIG. 2A shows a side view of the housing 6. A four-part structure of the housing 6 can be seen, and includes a cover 61, a base 62, a first lateral part 63 and a second lateral part 64. The individual parts 61 to 64 are discussed in greater detail with respect to FIGS. 3 to 7. A partial region 65 is indicated in the second lateral part 64, behind which a sensor is arranged in order to detect an attack on the electronic component 1.

A plan view of the housing 6 is shown in FIG. 2B, according to exemplary embodiments. The outer structure of the cover 61 of the housing 6 can be clearly seen in the plan view. The cover 61 has four through bores 611. A second data port of the electronic component 1 may be placed in each of these through bores 611. In addition, cooling ribs, which increase the surface area and thereby improve the dissipation of heat, may be incorporated, and are indicated on the cover 61 of the housing 6. In addition, four screws 66, with which the cover 61 is connected to the lateral parts 63 and 64 of the housing 6 in a mechanically detachable manner, are shown on the cover 61 of the housing 6.

A plan view of the base 62 of the housing 6 is shown in FIG. 2C, according to exemplary embodiments. In this view, the outer structure of the base 62 of the housing 6 can be seen clearly. The base 62 has three through bores 621 and 622. Two through bores 621 are provided for first data ports of the electronic component 1. Another through bore 622 is used for an energy port. In addition, cooling ribs 67, which increase the surface area and thereby improve the dissipation of heat, may be incorporated, and are indicated on the base 62 of the housing 6. In addition, four screws, with which the base 62 is connected to the lateral parts 63 and 64 of the housing 6 in a mechanically detachable manner, are shown on the base 62 of the housing 6.

A perspective view of the housing 6 is shown in FIG. 2D. In this view, the outer structure of the first lateral part 63 of the housing 6 can be clearly seen. In this particular embodiment, cooling fins 67, which increase the surface area and thus improve the dissipation of heat, are shown on the outside of the first lateral part 63 of the housing 6. The cooling ribs 67 extend continuously in parallel to the longitudinal axis in the y-direction and are shown over the entire outer surface of the first lateral part 63. Also indicated, but not shown, are cooling ribs 67 on the second lateral part 64 of the housing 6. The through bore 65 for a sensor in the second lateral part 64 is also indicated.

By installing the component housing 6 in the longitudinal direction of the pole 2, as shown in FIG. 1C, heat that is generated inside the component housing 6 is transferred to the outer surfaces of the component housing 6 and therefore distributed over the surface by the cooling fins 67. The arrangement of the cooling ribs 67 virtually parallel to the longitudinal direction of the pole 2 improves heat dissipation, for example in the case of colder air in the cavity of the pole 2.

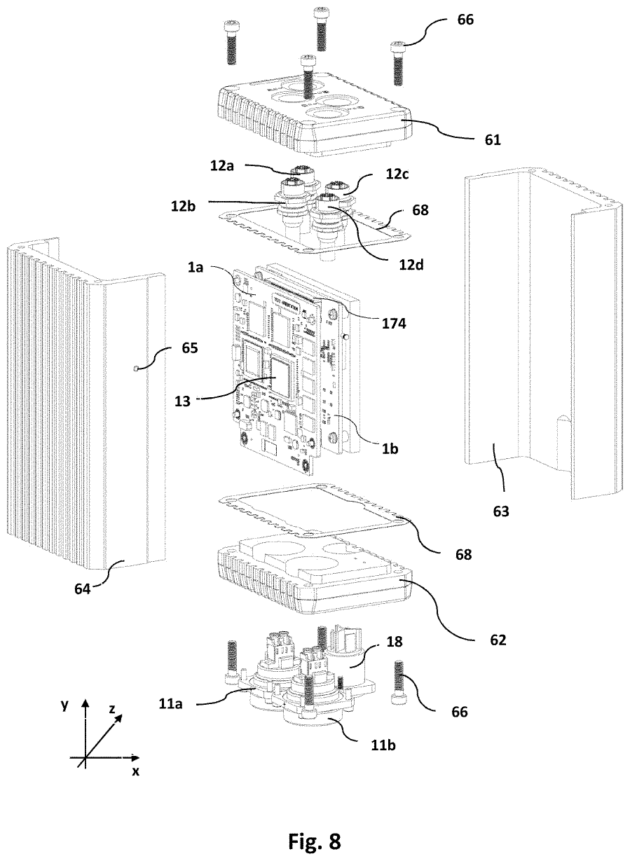

FIG. 3 shows a perspective view of an exemplary embodiment of a component housing 6 of an electronic component 1 in disassembled form (so-called exploded view) without the electronic component 1 (in contrast to FIG. 8). In contrast to FIG. 2D, the component housing 6 is now also shown from the inside. For the external features of the component housing 6, reference is made to the preceding description of FIG. 2.

In addition, according to this exemplary embodiment, the inner upper side of the second lateral part 64 of the component housing 6 shows 5 protrusions 641 which protrude into the interior of the component housing. These protrusions 641 make contact with corresponding components of a printed circuit board (not shown) directly (or, alternatively, possibly via further elements, such as heat paste or heat conducting pads). This printed circuit board houses a control unit for the electronic component. This control unit is a large heat source and must be cooled when the electronic component is in operation. By forming the inner side of the second lateral part 64 with the protrusions 641, a good thermal bridge (thermal coupling) is achieved. The entire second lateral part 64 is made of aluminum and forms a massive heat sink for the electronic component 1. In addition, the inner upper side of the second lateral part 64 of the component housing 6 also shows two (of four) fastening sleeves 642, by which the circuit board can be fixed to the second lateral part 64 in a mechanically detachable manner. This fixation further increases the thermal coupling.

Further according to this exemplary embodiment, eight screws 66 of the housing 6, with which the four parts 61 to 64 of the housing 6 are connected to one another, are shown in FIG. 3. A seal 68 is arranged between the base 62 and the two lateral parts 63, 64 of the housing 6. A second seal 68 is arranged between the cover 61 and the two lateral parts 63, 64 of the housing 6. The first lateral part 63 has a first connecting lip 69a which corresponds to a second connecting lip 69b of the second lateral part 64. The first lateral part 63 has a second connecting lip 69b which corresponds to a first connecting lip 69a of the second lateral part 64. These connecting lips 69a and 69b allow for the lateral parts 63, 64 to be plugged together and thus increase the stability of the housing 6 and the electromagnetic compatibility (EMC) of the housing. The seals 68 and the connecting lips 69a, 69b allow for a high protection class, for example protection class IP67, of the housing 6 to be achieved. This high protection class guarantees that the electronic component 1 is protected against splash water. The pole 2 can thus be cleaned with high pressure water without the electronic component 1 being damaged.

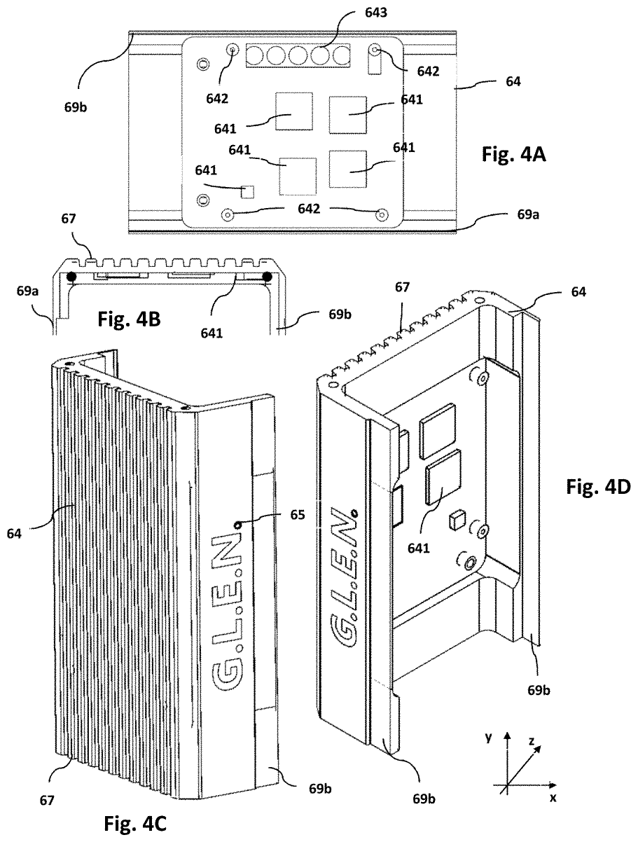

Four different views of the second lateral part 64 of the component housing 6 of an electronic component 1 that was described with respect to FIGS. 2 and 3 are shown in FIGS. 4A-4D.

In FIG. 4A, an inner plan view of the second lateral part 64 is shown. The protrusions 641 and the fastening sleeves 642 already described with respect to FIG. 3 are shown again. In addition, a region 64 is shown.

In FIG. 4B, a plan view of the second lateral part 64 is shown. The cooling ribs 67 and the two connecting lips 69a, 69b are shown again. In this illustration, the difference in thickness between the first connecting lip 69a and the second connecting lip 69b is clearly apparent. This difference in thickness allows for the two lateral parts 63 and 64 of the housing 6 to be simply and stably plugged into one another.

FIG. 4C shows an outer surface of the second lateral part 64. Here, too, it is apparent that the cooling ribs 67 are formed continuously in parallel to a longitudinal axis y in order to make optimal cooling of the electronic component 1 possible. Especially by means of the chimney effect of a pole 2, the heat is quickly transported away from the respective heat source.

FIG. 4D again shows the interior view of the second lateral part with the protrusions 641 and the fastening sleeves 642, as has already been shown and described with reference to FIG. 3.

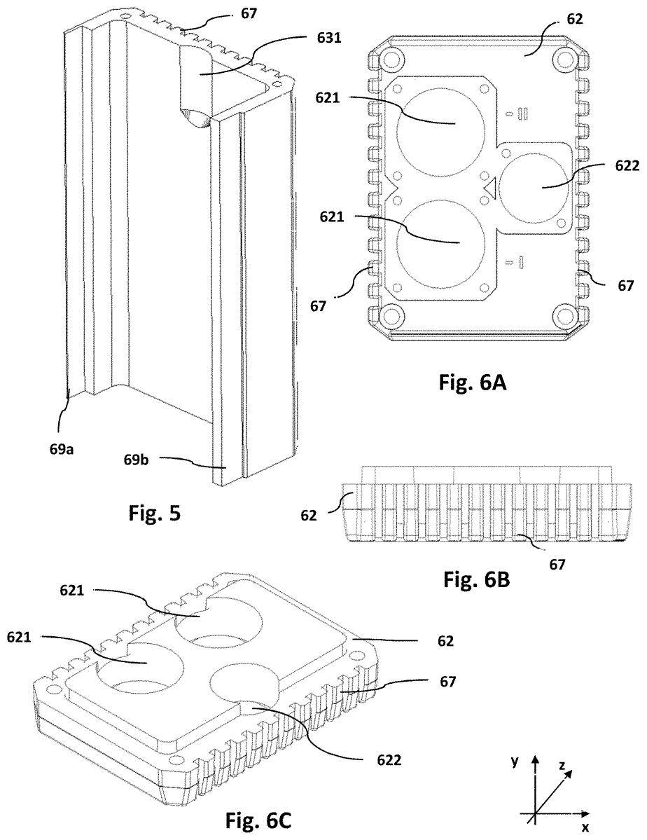

FIG. 5 shows a perspective view of the first lateral part 63 of the component housing 6 of the electronic component 1 that was described with respect to FIGS. 2 and 3. Inside, the first lateral part 63 has a recess 631 for receiving an energy port 18 (not shown). The first connection lip 69a and the second connection lip 69b, which correspond to the respective connection lips 69a, 69b of the second lateral part 64, are also shown.

FIGS. 6A-6C show three views of the base 62 of the component housing 6 of the electronic component 1 that was described with respect to FIGS. 2 and 3. FIG. 6A corresponds to the illustration of FIG. 2C and reference is made to the associated description. FIG. 6B shows a front view of the base 62 with the cooling ribs 67. In FIG. 6B, a protrusion for achieving a good mechanical and stable connection with the two lateral parts 63, 64 of the housing 6 can also be seen. FIG. 6C shows a perspective view of the base 62 with the three through bores 621, 622 for the ports 11a, 11b and 18 of the electronic component 1. The cooling fins 67 are also indicated.

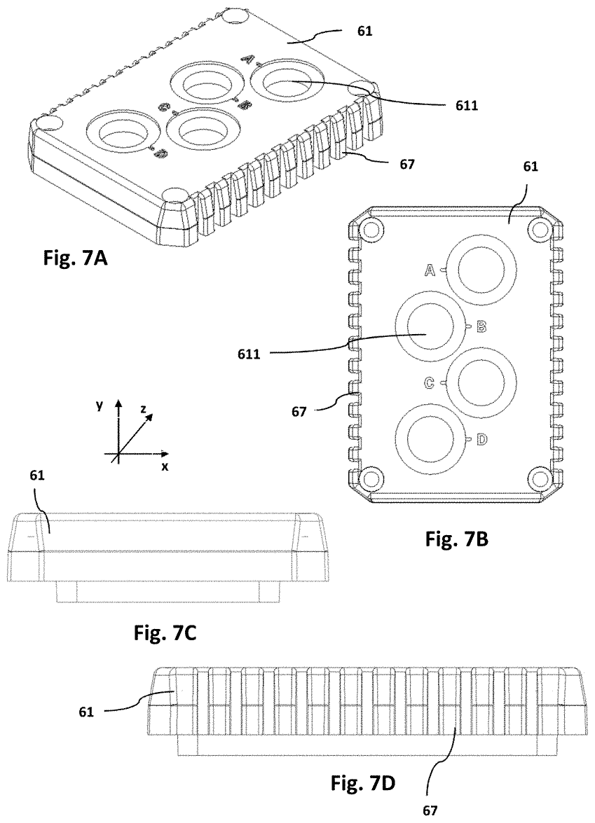

FIGS. 7A-7D show four different views of the cover 61 of the component housing 6 of the electronic component 1 that was described with respect to FIGS. 2 and 3.

FIG. 7A shows a perspective view of the cover 61 with the four through bores 611 for the ports 12a, 12b, 12c and 12d of the electronic component 1. The cooling fins 67 are also indicated. The cooling fins 67 are indicated as well.

FIG. 7B corresponds to the illustration of FIG. 2B and reference is made to the associated description.

FIG. 7C shows a side view of the cover 61. In FIG. 7D, a protrusion for achieving a good mechanical and stable connection with the two lateral parts 63, 64 of the housing 6 is apparent.

FIG. 7D shows a front view of the cover 61 with the cooling fins 67. In FIG. 7D, the protrusion for achieving a good mechanical and stable connection with the two lateral parts 63, 64 of the housing 6 is apparent.

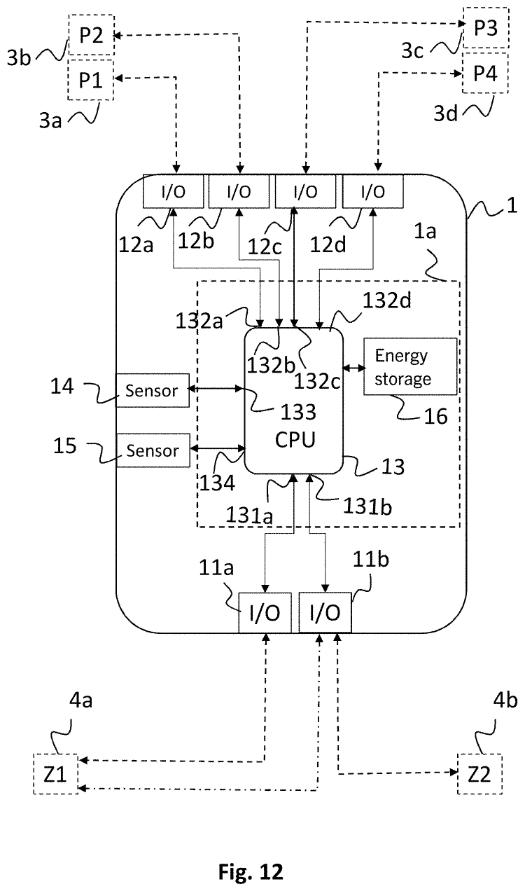

FIG. 8 shows a perspective view of the component housing 6 of the electronic component 1 that was described with respect to FIG. 3, but in disassembled form (exploded view), and this time with the electrical component 1. The elements already presented in FIG. 3 are not described again here. Four ports 12a, 12b, 12d, 12d are introduced into the corresponding through bores 611 in the cover 61 of the housing. The ports 12a, 12b, 12d, 12d are selected to be appropriately stable in order to be able to absorb shear forces during installation and uninstallation in the pole 2 without the respective port being destroyed. The four ports 12a, 12b, 12d, 12d are connected to four second data ports 132a-132d (see FIG. 12) of the first board 1a. Reference is made to the description of the electrical function in FIGS. 10 to 13.

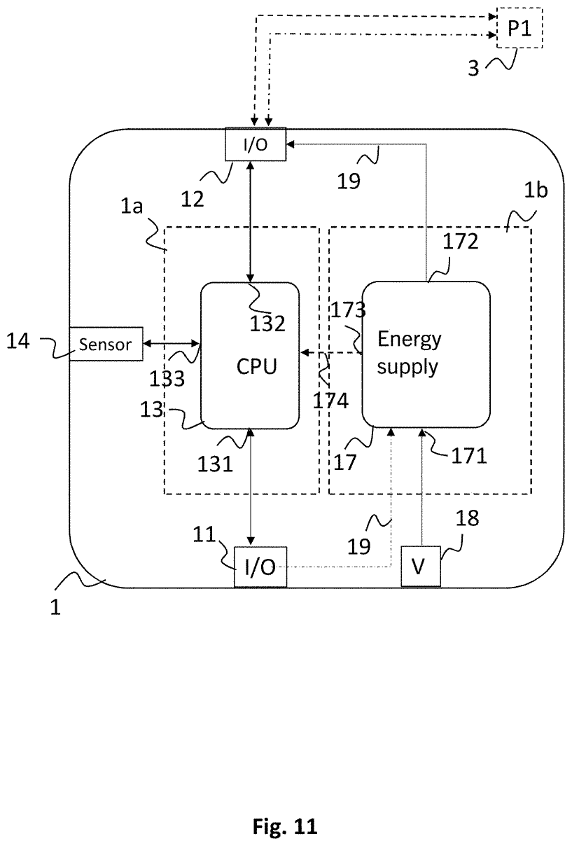

According to this exemplary embodiment, two SFP ports 11a and 11b are introduced into the corresponding through bores 621 in the base 62 of the housing. The SFP ports 11a and 11b are selected to be appropriately stable in order to be able to absorb shear forces during installation and uninstallation in the pole 2 without the respective port being destroyed. The two ports 11a, 11b are connected to two first data ports 131a, 131b (see FIG. 12) of the first board 1a. Reference is made to the description of the electrical function with respect to FIGS. 10 to 13. An energy port 18 is inserted into the corresponding through bore 622 in the base 62 of the housing. The port 18 is connected to an energy port 171 (see FIG. 11) of the second board 1b.

The two boards 1a and 1b are also described in detail with respect to FIGS. 10 to 13. The boards 1a, 1b may be designed as PC/104 form factor and are connected to one another in an electrically conductive manner by means of a connector 174. The control unit 13 is also indicated on the first board 1a.

FIGS. 9A-9D show a variant for mechanically fixing a component housing 9 of the electronic component 1 according to a further exemplary embodiment. In FIG. 9A, a holding rail 72 is shown for this purpose. This holding rail 72 has a first holding element 73 which is connected to the holding rail 72 mechanically detachable (screwed, not shown) or non-detachable (riveted, welded, shown here) manner. The holding rail 72 has a plurality of through bores in order to be able to be connected to a fastening element 24 (not shown) of FIG. 1B in a mechanically detachable manner. In FIG. 9A, a second holding element 74 allowing for a clamping connection 71 with the holding rail 72 by means of laterally formed clamping lugs (two per side) is also shown. In FIG. 9B, the second holding element 74 is mounted on the holding rail 72 such that it can move in the y-direction. The second holding element 74 can be moved in the y-direction on the holding rail 72 and thus enables a mechanically releasable fixation of the component housing 6 in the cavity of the pole 2, as shown in FIGS. 9C and 9D.

In FIG. 9C, a holding region 60 in the housing 6 is shown. The holding region 60 is arranged as a slot in the cover 61 of the housing 6. A second holding region 60, which is arranged as a slot in the base 62 of the housing 6, is not shown. A corresponding region of the first or second holding element 74 engages in these slots as holding region 60, see FIG. 9D, whereby the holding rail 72 (mechanically connected to a fastening element of the pole 2) is fixed by means of the clamping connection 71 in the cavity of the pole 2.

Latching and/or screw and/or magnetic and/or clamping connections, by which a mechanical fixation in the cavity of the pole 2 can also be implemented, are not shown.

FIG. 10 shows an exemplary embodiment of a simplified block diagram of an electronic component 1 within a schematically illustrated pole portion of a pole 2 as an example of an outdoor device. With this exemplary embodiment, it is possible to upgrade poles 2 of cities, municipalities and companies to communication and control nodes and thus enable a smart city concept.

Here, the pole 2 is a light pole, as will be explained in greater detail with respect to the following FIGS. 13 to 15, for example. The pole is hollow on the inside and has a pole opening 21 that can be closed in a substantially light-tight manner by a cover or door (not shown). In the interior of the pole 2, there is an electronic component 1, hereinafter simply referred to as switch 1, that is a network switch.

According to this exemplary embodiment, the switch 1 is integrated in a metal housing with, for example, protection class IP67. The switch 1 provides at least a first port 11 on the input side, the port being connected to a first data port 131 of a control unit 13 in the switch 1. The first data port 131 is configured to transmit a data signal between the switch 1 and a network component, hereinafter referred to simply as the data center 4 or backbone 4, remote from the pole 2. The data signal at the first port 11 has a bit rate of 10 Gbit, for example, but could also have only 1 Gbit or 100 Gbit. The data center is, for example, a city or state data center that is sometimes several hundred kilometers away from pole 2. The network is a Metropolitan Area Network, or MAN for short. The data signal may be connected to the first port 11 via optical waveguide. The data signal may be transmitted by a mono-mode method when the distance between the switch 1 and the remote network component 4 exceeds a certain threshold value. The data signal may be transmitted by a multi-mode method if the distance between switch 1 and the remote network component 4 falls below a certain threshold value.

On the output side, the switch 1 includes at least one second port 12 connected to a second data port 132 of the control unit 13 in the switch 1. The second data port 132 is configured to transmit a data signal between the switch 1 and a peripheral 3. The data signal at the second port 12 is, for example, a 1 Gbit Ethernet interface. This data signal may have a Power-On-Ethernet, PoE, functionality via which a predefined maximum power, for example 25 W, can be supplied to the peripheral 3. The data signal is may be connected to the second port 12 via copper.

The switch 2 has a sensor 14 built into the housing. In the particular embodiment depicted in FIG. 10, this sensor 14 is a light sensor connected to a sensor signal port 133 at the control unit 13. The light sensor is installed at the housing of the switch 1 from the inside in order to detect light incident in the pole opening 21. A partial region of the housing of the switch 1 is thus transparent to the incident light so that the sensor 14 located behind the region in the housing can detect the incident light. Alternatively, the housing is provided with a through bore in which the sensor 14 is disposed in order to be able to detect the incident light. Alternatively, the sensor 14 may also be placed outside on the housing of the switch 1.

In normal operation, the pole opening is closed so that a constant very low incidence of light is detected inside the pole. A pole door could also close the pole opening 21 of the pole 2 in a substantially light-tight manner. When the pole opening 21 is opened, for example the pole door or pole lid (not shown) is unlatched or unlocked, i.e. actuated, significantly more light enters into the interior of the pole 2 (even at night). The sensor 14 senses the higher incidence of light and generates an increase (for example abruptly or continuously) of the sensor signal amplitude over a certain period of time. The sensor signal is evaluated in the control unit 13 and this increase is recognized. The control unit 13 assesses this as a deviation from normal operation and informs (alarms) the backbone 4 accordingly. The alarm to the remote network component 4 could be issued when the light sensor 14 detects a predefined illuminance that is, for example greater than 10 lux or greater than 7 lux. In the control unit 13, a trigger delay or an averaging of the sensor values (also referred to as mini hysteresis) is provided for a specific period of time. This means that light fluctuations in the range of, for example, a few 100 ms are not to be assessed as an alarm. This means that no false alarms are triggered in the event of, for example, a thunderstorm.

Alarming the backbone 4 may comprise communicating an ID of the switch 1 or a location of the pole 2 or both with a corresponding error code (e.g., incidence of light detected). The backbone 4 decides on suitable measures. It could classify the incident as normal if maintenance on the pole 2 in the backbone 4 is known. It could classify the incident as an attack and move the existing data connection between the peripheral 3 and the backbone 4 to a quarantine region and thus continue to monitor the incident in a secure environment. Alternatively, it could cut off the data connection to the switch 1 or cause the switch to interrupt the data connection between the backbone 4 and the peripheral 3. It could order the deletion of the memory space in the control unit 13.

In any case, the switch 1 is better secured and in particular the sensitive data (IP addresses, private keys, signature keys, configuration data, passwords) of the switch 1 are better secured. A pole 2 installed in a forlorn area with a switch 1 arranged therein having a direct connection to the backbone 4 is thus better protected against attacks.

The sensor 14 used in the exemplary embodiment of FIG. 10 may alternatively, or additionally also, be a motion sensor or a micro switch. These types of sensors detect a movement of the housing or the opening of the housing of the switch 1. These measures are directly assessed to be an attack by the control unit and trigger an immediate deletion of the above-mentioned sensitive data in the memory of the switch. The switch is then no longer configured and may neither establish nor forward a data connection to a backbone 4 or to a peripheral 3. Thus, the removal of the switch 1 or the opening of the switch 1 does not result in unauthorized manipulation of the data connection, and this effectively prevents sensitive data to be read out or information to be tapped by the attacker.

FIG. 11 shows a simplified block diagram of another exemplary embodiment of electronic component 1. The device 1 in FIG. 11 corresponds to the electronic component 1 in FIG. 10 and only includes further elements to which reference is made below. The components already presented in FIG. 10 are not repeated here.

The electronic component 1, hereinafter referred to as switch 1, includes a first board 1a comprising the control unit 13. In addition, the switch 1 includes a second board 1b comprising an energy supply unit 17. Both of the boards 1a, 1b are connected to one another via a connector 174 and are implemented together in the metal housing of the switch 1. Both of the boards 1a, 1b may be standard form factor boards, such as having the form factor PC/104. This form factor PC/104 allows for scaled-down construction of the switch 1 and, thanks to this scaled-down construction, the integration of the switch 1 into a pole 2 with a very small diameter is possible in a simplified manner. Both of the boards 1a, 1b may each have a form factor different from the form factor PC/104. The form factor also allows for several boards to be arranged on top of one another, so-called “stacking”, and to be connected using connectors 174. This improves the electromagnetic compatibility of the components with one another.

The switch 1 includes, for example, a third port 18 to which an energy supply is applied. This third port 18 is led to a port 171 of the energy supply unit 17. Alternatively, as shown here as a dash-dot line, an energy supply via the first port 11, for example as a PoE signal, is provided. In this case, the third port 18 may be omitted and the structure is simplified.

The energy supply unit 17 provides an energy supply for the peripheral 3 via an energy output 172. This energy supply is applied as a PoE signal 19 to the second port 12 of the switch 1 and thus provided to the peripheral 3 via a port along with the data signal of the second data port 132 of the control unit 13. The use of the PoE signals 19 simplifies the wiring work in the pole 2 considerably and the peripherals 3 can be supplied with energy by the switch 1. Further external energy source(s) for supplying the peripherals 3 may thus be omitted.

The energy supply unit 17 also provides an energy supply for the control unit 13 via an energy output 173. This energy supply is made possible, for example, via a connector 174. Further external energy source(s) for supplying the control unit 13 may thus be omitted.

FIG. 12 shows a simplified block diagram of a further exemplary embodiment of an electronic component 1. The electronic component 1 of FIG. 12 corresponds to the electronic component 1 of FIG. 10 and the first board 1a of FIG. 11 and includes further elements to which reference is made below. The components already presented in FIG. 10 and FIG. 11 are not repeated here.

In contrast to FIG. 10 or FIG. 11, two first ports 11a, 11b are now provided on switch 1 as depicted in FIG. 12. A first backbone 4a is connected to the first port 11a. A second backbone 4b is connected to the second port 11b. This may increase the bandwidth of the switch 1 and consequently could lead to an improved functionality of the peripherals 3a to 3d. Alternatively—as shown in FIG. 12 as a dash-dot line—a first backbone 4a is connected to the second port 11b. This may increase the bandwidth of the switch 1 and could consequently lead to an improved functionality of the peripherals 3a to 3d. For example, two 10 Gbit SFP modules may be used as ports 11a, 11b. The two first ports 11a, 11b are each connected to first data ports 131a, 131b of the control unit 13, respectively.

In a further difference to the exemplary embodiments depicted in FIG. 10 or FIG. 11, four second ports 12a, 12b, 12c, 12d are now provided on the switch 1 as depicted in FIG. 12. A first peripheral 3a is, or can be, connected to the second port 12a. A second peripheral 3b is, or can be, connected to the second port 12b. A third peripheral 3c is, or can be, connected to the second port 12c. A fourth peripheral 3d is, or can be, connected to the second port 12d. The four second ports 12a, 12b, 12c, 12d are each connected to second data ports 132a, 132b, 132c, 132d of the control unit 13, respectively. Thus, according to this specific configuration, up to four peripherals 3 can be connected to a switch 1 at the same time. However, the number of connectable peripherals is not restrictive. For example, according to certain exemplary embodiments, up to 24 peripherals 3 can be connected to a switch 1. For example, each peripheral 3 is provided with a 1 Gbit connection as ports 12a, 12b, 12c, 12d.

In a further difference to the exemplary embodiments depicted in FIG. 10 or FIG. 11, at least two sensors 14, 15 are now provided in switch 1 as depicted in FIG. 12. The first sensor 14 is the light sensor already described in FIG. 10, the sensor signal of which is connected to the sensor signal port 133 of the control unit 13. The second sensor 15 is the micro switch already indicated in the description of FIG. 10, the sensor signal (or switching signal) of which is connected to a second sensor signal port 134 of the control unit 13. By using two sensors 14, 15 and corresponding evaluation of the sensor signals at the ports 133, 134 of the control unit 13, a two-stage alarm or protection method may be used. Accordingly, if an increased incidence of light is recognized by the light sensor 14 (=first stage of the attack), only the backbones 4a, 4b could be alarmed and the measures already described in FIG. 10 could be taken. If the switching element 15 recognizes that the housing has been opened (=second stage of the attack), the deletion/overwriting of the sensitive data from the memory of the switch 1 could be initiated. Thus, the operability of the network is maintained for as long as possible and opening the pole 2 does not automatically have to result in an interruption of the data connection. Thus, unannounced maintenance activities may also be monitored, and the functionality of the network is maintained. However, if the second stage of an attack is detected, the sensitive data can be reliably deleted.

In a further difference to the exemplary embodiments depicted in FIG. 10 or FIG. 11, an energy storage 16 is now provided as depicted in FIG. 12. This energy storage 17, for example a storage capacitor with several 100 millifarads to several farads, ensures the operation of the switch 1 even in the event of brief energy supply fluctuations and allows for an attack to be detected even with removed energy supply. In this way, the sensitive data can be reliably deleted, even if the energy supply has already been switched off.

In this particular embodiment, the first board 1a is connected to a second board 1b via a connector 174 and receives three different voltages, i.e. 50 V, 5 V and 3.3 V, via the connector from the second board 1b. An energy μC uses the supplied voltages to provide a supply voltage for the control unit 13 and PoE signals for the four second ports 12a, 12b, 12c, 12d. The ports 11a, 11b are also supplied with energy. The two sensors are not accommodated on the board 1a but are arranged in suitable places on the housing and connected to the control unit 13 by wire, i.e., via a “Sensor I/O” plug-in connector. The control unit 13 is connected to two first ports 11a, 11b and four second ports 12a, 12b, 12c, 12d.

In addition, status LEDs may be provided which visualize the state of the switch 1 to the outside (outside the housing of the switch 1). For example, a status LED may indicate whether there is an energy supply, a status LED may indicate whether the switch is turned on, a status LED may be two-colored and indicate whether there is a data connection with the backbone 4a, and a status LED may be two-colored and indicate whether there is a data connection with the backbone 4a or 4b (depending on how it was wired). In addition, LEDs may be provided which indicate the connection status with the respective peripherals 3a, 3b, 3c, 3d. These LEDs may be arranged such that they can be seen from the outside via through bores on the housing or transparent portions in the housing.

Further, the board 1a may have a service port via which the control unit 13 can be updated and maintained by means of a driver module.

The second board 1b includes, for example, a third port 18 to which an energy supply, for example 110 VAC to 230 VAC at 50 Hz or 60 Hz, can be applied. This third port 18 is led to a port 171 of the energy supply unit 17.

According to this particular embodiment, the energy supply unit 17 provides an energy supply for the peripheral 3 via an energy output 172. A power supply with, for example, a wide range input with an output voltage of 50 V and 3 A, may be implemented for this purpose. By mounting the power supply module directly on the metal housing, the waste heat from the power supply may be dissipated. The housing of the switch 1 is thus also a heat sink for the power supply. For example, the cooling capacity of the housing of the switch may be at least 1 K/W. As a result, there is no need for additional fans or heat pipes. This energy supply is applied, for example, as a PoE signal 19 via the connector 174 to the second port 12 of the switch 1 and is thus provided to the peripheral 3 via a port together with the data signal from the second data port 132 of the control unit 13.

The energy supply unit 17 may also provide an energy supply for the control unit 13 via an energy output 173. For this purpose, a DC-DC switching converter with an output voltage of 5 V and 6 A may be implemented, which is supplied by the power supply described above. The energy supplies are forwarded to the first board 1a, for example via the connector 174. As a result, further external energy source(s) for supplying the control unit 13 or the peripherals 3 may thus be omitted.

FIG. 13 shows a true-to-scale exemplary embodiment of an exemplary pole 2 in which a switch 1, according to an exemplary embodiment thereof, is arranged. In this particular embodiment, the pole has three pole openings 21 arranged one above the other, each of which can be locked by means of a triangular door lock. Each pole opening 21 can be closed with a pole door measuring, for example, 100×400 millimeters. The housing of the device must be insertable into the interior of the pole 2 through this pole door size, so that the external dimensions of the housing are limited to these pole opening sizes. The diameter of pole 2 at the base of the pole is, for example, 246 millimeters. An equipment bar extends inside the pole and, for example, is designed as atop hat rail or as a rail. The housing 6 of the switch is arranged on this equipment bar.

FIG. 14 shows three true-to-scale exemplary embodiments for exemplary pole openings 21 in poles 2, through which a device 1, according to an exemplary embodiment thereof, is arranged in a pole 2. It is intended to provide only one housing for the device 1, so that the dimensions of the smallest pole opening 21, such as those of the pole type LM3-SC, limit the external dimensions of the housing of the device. With the pole type LM3-SC as an example, the diameter on the level of the pole opening 21 is between 130.85 and 136.07 millimeters and the pole opening 21 has dimensions of 85 by 300 millimeters.

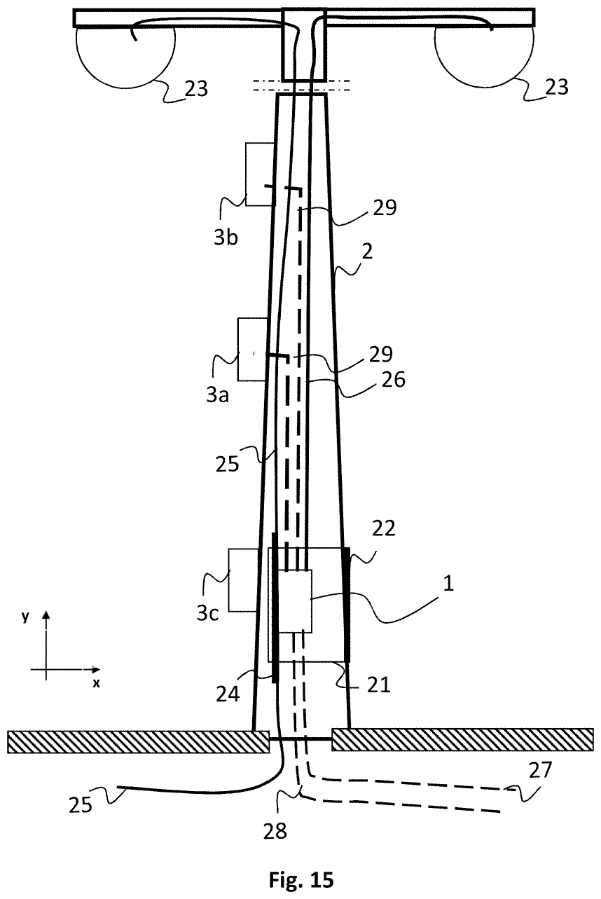

FIG. 15 shows an exemplary embodiment of a system having a pole 2 with a switch 1 arranged therein. The pole 2 may be of the type of pole as shown in FIG. 13 or 14. The switch 1 may correspond to one of the switches of the type in FIGS. 10 to 13. In this particular embodiment, the switch 1 is inserted through the pole opening 21 into the interior of the pole 2 and is mechanically fastened there to a top-hat rail 24, for example by means of a claw, clamp and/or screw connection. Alternatively, in a well-secured environment, a magnetic connection may also be used to fasten the switch 1 inside the pole 2.

According to the embodiment of FIG. 15, the pole 2 has two lighting sources 23 as a functional unit. These lighting sources 23, for example LED lighting, are connected either to their own energy supply 25 or to a PoE supply 26 of the switch 1 and are accordingly supplied with power thereby.

Further, a peripheral 3b, for example a traffic sensor, is attached to the pole 2 and is connected to a backbone by means of a data connection 29 via the switch 1 (see the indicated data connection 27 to the backbone).

In addition, a peripheral 3a, for example a camera or a WLAN-AP, is attached to the pole 2 and connected to a backbone by means of a data connection 29 via the switch 1 (see the indicated data connection 27 to the backbone).

Additionally, a peripheral 3c, for example an electric vehicle charging station, is attached to the pole 2 and is connected to a backbone by means of a data connection 29 via the switch 1 (see the indicated data connection 27 to the backbone).

Within the scope of the invention, all elements described and/or drawn and/or claimed can be combined with one another as desired.

What is claimed is:

1. A device with an electronic component arranged operably in a cavity of said device, said device comprising:
an electronic component electrically connected to an electrical functional unit of said device, wherein said electronic component:
has a component housing, wherein said component housing is a heat sink for said electronic component and is fixed completely spaced apart from inner sides of said device; and
is mechanically fixed by said component housing in a cavity of said device; and
an opening for inserting said electronic component into the cavity.

2. The device according to claim 1, wherein said device is a pillar-like hollow body.

3. The device according to claim 2, wherein said device is a pole.

4. The device according to claim 1, wherein said device includes a fastening element in the cavity to mechanically fix said component housing in the cavity of the device, wherein said fastening element is at least one of:
arranged in parallel to a longitudinal axis of said device and in said device; and
mechanically fixed on an inner longitudinal side of said device.

5. The device according to claim 4, wherein said component housing has at least one holding region on an outer side of said component housing, wherein a holding device engages with said holding region in a form-fitting manner, wherein said holding device is operably connected to said fastening element of said device.

6. The device according to claim 5, wherein said holding device is connected to said fastening element by at least one of:
mechanically; and
magnetically.

7. The device according to claim 6, wherein said holding device is mechanically connected to said fastening element of said device by at least one of:
a clamping connection;
a latching connection; and
a screw connection.

8. The device according to claim 1, wherein said component housing is a heat sink for a control unit within said component housing of said electronic component.

9. The device according to claim 1, wherein said component housing is a heat sink for an energy supply unit within said component housing of said electronic component.

10. The device according to claim 8, wherein said component housing has at least one protrusion on an inner side of said component housing, wherein said protrusion extends into an interior of said component housing and is directly opposite said control unit of said electronic component and contacts said control unit of said electronic component directly.

11. The device according to claim 9, wherein said component housing has at least one protrusion on an inner side of said component housing, wherein said protrusion extends into an interior of said component housing and is directly opposite said energy supply unit of said electronic component and contacts said energy supply unit of said electronic component directly.

12. The device according to claim 1, wherein said electronic component has ports on at least one of:
a top side; and
a bottom side of said component housing opposite said top side, wherein said top side and said bottom side of said electronic component are oriented substantially perpendicular to a longitudinal axis of said device.

13. The device according to claim 12, wherein said ports are at least one of:
electrical; and
optical.

14. The device according to claim 12, wherein said component housing is formed in a plurality of parts and the ports on said component housing are arranged in at least one of:
an upper part of said component housing; and
a lower part of said component housing.

15. The device according to claim 1, wherein said component housing has a plurality of parts, a first lateral part of said component housing being detachably connected to a second lateral part of said component housing in a form-fitting manner.

16. The device according to claim 1, wherein said component housing includes at least one printed circuit board with a form factor of PC/104.

17. The device according to claim 1, wherein said electronic component comprises an energy supply unit, wherein said energy supply unit includes:
a first energy port for supplying a supply energy external to said component; and
at least one second energy port for diverting a supply energy for said electrical functional unit of said device.

18. The outdoor device according to claim 17, wherein said second energy port provides a Power-on-Ethernet (PoE) energy signal combined with a data signal to be transmitted between said electronic component and said electrical functional unit of said device.

19. The outdoor device according to claim 1, wherein said electronic component comprises a control unit, wherein said control unit comprises:
at least one first data port configured to transmit a data signal between said electronic component and a network component remote from said device; and
at least one second data port configured to transmit a data signal between said electronic component and said functional unit of said device, wherein said control unit is configured to forward data communication between said remote network component and said functional unit of said device.

20. The outdoor device according to claim 1, wherein:
said electronic component includes a sensor on said component housing configured to provide a sensor signal; and
a control unit of said electronic component is configured to:
evaluate the sensor signal;
detect a change in the sensor signal; and
alert a network component remote from said device when the change in the sensor signal is detected by said control unit.
